(19) United States
(12) Patent Application Publication
(10) Pub. No.: US 2026/0279715 A1
(43) Pub. Date: Sep. 17, 2026

(54) MULTI-BEAM CHARGED PARTICLE MICROSCOPE FOR INSPECTION WITH REDUCED CHARGING EFFECTS

(71) Applicant: Carl Zeiss MultiSEM GmbH, Oberkochen (DE)

(72) Inventors: Stefan SCHUBERT, Oberkochen (DE); Thomas DIETERLE, Murrhardt (DE); Bjoern MIKSCH, Heidenheim (DE); Ingo MUELLER, Aalen (DE)

(21) Appl. No.: 19/667,863

(22) Filed: May 5, 2026

Related U.S. Application Data
(63) Continuation of application No. PCT/EP2024/025311, filed on Oct. 24, 2024.

(30) Foreign Application Priority Data
Nov. 7, 2023 (DE) 10 2023 211 031.8

(51) Int. Cl. H01J 37/02; H01J 37/26; H01J 37/28

(52) U.S. Cl. CPC H01J 37/026; H01J 37/265; H01J 37/28; H01J 2237/0044; H01J 2237/2817

(57) ABSTRACT

A multi-beam charged particle system and a method of operating a multi-beam charged particle system reduce the impact of charging. Surface charge present on a surface of a sample, which is for example generated during a first image scanning operation, is compensated during a second scanning operation in mirror mode for charge compensation.

### CROSS-REFERENCE TO RELATED APPLICATIONS

The present application is a continuation of, and claims benefit under 35 USC 120 to, international application No. PCT/EP2024/025311, filed Oct. 24, 2024, which claims benefit under 35 USC 119 of German Application No. 10 2023 211 031.8, filed Nov. 7, 2023. The entire disclosure of each of these applications is incorporated by reference herein.

### FIELD

The disclosure relates to a multi-beam charged particle microscope with reduced charging of samples and a method of operating a multi-beam charged particle microscope for inspecting semiconductor features with reduced charging.

### BACKGROUND

WO 2005/024881 A2 discloses an electron microscope system which operates with a multiplicity of electron beamlets for parallel scanning an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlets is formed whose cross section is defined by the cross section of the respective opening. The plurality of primary charged particle beamlets are focused by an objective lens on a surface of a sample and trigger secondary electrons or backscattered electrons to emanate as secondary electron beamlets from the sample, which are collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated.

Generally, the imaging contrast of a scanning electron microscope generally depends on the signal generated by secondary electrons, which depends on the secondary electron (SE) yield per primary electron and a geometrical collection efficiency of the electron microscope. The SE yield generally depends on material characteristics and the kinetic energy of the primary electrons. However, the SE yield can be influenced by charging effects of the sample surface. Charging effects can occur at local capacities or insulators, which accumulate charges and generate deteriorating electrical fields to the primary as well as secondary electron beamlets.

Different methods have been proposed to mitigate charging effects. Flood guns are widely used to pre-charge a sample surface. An example for a multi-beam charged particle beam system is given in U.S. Pat. No. 11,239,053. However, in some cases, application of this method has turned out to significantly disturb precision imaging. In German Patent application 102022211883.9, filed Nov. 10, 2022, a selected primary electron beam energy is used to operate at a point where secondary electron emission and incident primary electron current is in balance. Thereby, charging is minimized. However, to minimize charging, different material compositions present at a surface of a wafer use different specific kinetic energies of primary electrons, and the kinetic energy of primary beamlets cannot be adjusted individually during an image scan.

U.S. Pat. No. 6,563,114 provides background information. DE 10 2021 105 201 A1 and its family document WO002022069073A1 provide background information.

### SUMMARY

The present disclosure seeks to mitigate charging effects or avoid charging of samples during wafer inspection.

The present disclosure seeks to provide an improved multi-beam charged particle imaging system and an improved method of operation of a multi-beam charged particle beam system, which reduce charging effects during the inspection of semiconductor samples.

The disclosure provides a multi-beam charged particle imaging system and a method of operation of a multi-beam charged particle beam system, by which, for example, surface charges generated during scanning image acquisition with a plurality of primary charged particle beamlets can be compensated or balanced. Surface charges can be at least partially removed, such that a subsequent, second image acquisition can be performed with relatively high accuracy and with at least a reduction of deteriorating effects of surface charges. The method comprises a scanning operation step for charge compensation. The scanning operation for charge compensation comprises setting a negative voltage difference VD2 to a sample mounted to the sample stage, such that primary charged particle beamlets are reverted in propagation direction before reaching uncharged regions of the surface of the sample. This mode of operation is also called a mirror mode. The second, negative voltage difference VD2 can be adjusted such that primary charged particles only reach the surface of a sample at the regions, where positive surface charges are present. Surface charges can for example be generated during a first, preceding image acquisition, or present at a surface of a sample even before a first image acquisition. Thereby, positive surface charges can be removed, and a charging can be at least partially compensated.

In a first aspect, the disclosure provides a method of operating a multi-beam charged particle beam system. The method comprises a first or image scanning operation step A and a second scanning operation step B for charge compensation. The method comprises an acquisition of an image of a surface segment of a wafer surface during the first or image scanning operation step A and at least partially compensating a surface charge on the surface segment during second scanning operation step B for charge compensation. The method comprises setting a first, positive voltage difference VD1 during the first or image scanning operation step A. The first, positive voltage difference VD1 is selected and adjusted such that primary charged particle beamlets reach the sample surface at a landing energy LE within a range of landing energies, where a secondary and backscattered electron yield, generated by an individual primary charged particle beamlet, exceeds an incident beam current of the primary charged particle beamlet. Within the range of landing energies, positive surface charges are generated at least at regions of the surface of the sample during the image scanning operation. The method further comprises setting a second, negative voltage difference VD2 during the second scanning operation step B for charge compensation. The second, negative voltage difference VD2 is selected such that primary charged particle beamlets are reverted in propagation direction before reaching uncharged regions of the surface of the sample, and reach the surface of a sample at the regions, where positive surface charges are present, as for example generated during the first or image scanning operation step A. At regions, where surface charges are present, primary charged particles are impinging on the surface and are compensating the positive surface charge.

For example, the positive surface charge is built on a surface during the first or image scanning operation step A. For example, with electrons as primary charged particles, secondary and backscattered electrons exceed during the first or image scanning operation step A the incident current of primary electrons, such that positive surface charges are generated. During the second scanning operation step B for charge compensation, primary electrons impinge surface areas with positive surface charge and are compensating the positive surface charges at least partially. During the second scanning operation step B for charge compensation, the kinetic energy of primary electrons is insufficient to reach surface areas without positive surface charges and no additional charging is generated at surface areas without a positive surface charge. In an example, the absolute value of the second, negative voltage difference VD2 is less than 100V, for example 50V, for example 10V or 5V, for example 1V. Thereby, for example a low threshold for primary electrons is set, such that primary electrons impinge on areas with even low positive surface charges.

In an example, the second scanning operation step B for charge compensation is performed before or previous to a first or image scanning operation step A, and a charged present at a surface of a sample before image acquisition is reduced or removed by the second scanning operation step B for charge compensation.

In an example, the method comprises iteratively repeating the first or image scanning operation step A and the second scanning operation step B for charge compensation. In an example, the first or image scanning operation step A and the second scanning operation step B for charge compensation are iteratively repeated each sequence of scanning lines, wherein the sequence of scanning lines comprises one, two, ten or more scanning lines. In an example, the second scanning operation step B for charge compensation is performed during a fly-back of each primary charged particle beamlet during first or image scanning operation step A. In an example, the second scanning operation step B for charge compensation is performed at a first inspection site, before a wafer is moved to a second inspection site adjacent to the first inspection site. Thereby, an influence of a surface charge on an adjacent pre-exposed surface segment to a second inspection site is reduced. Thereby, a charging of a surface segment is reduced before a subsequent scanning image acquisition step of an adjacent surface segment is performed. In an example, the second scanning operation step B for charge compensation is limited to a scanning range at a border or edge of a surface segment. Thereby, a charging at a border or edge of a surface segment is reduced before a subsequent scanning image acquisition step of an adjacent surface segment is performed.

In an example, the method further comprises a setting adjustment step S. Setting adjustment step S comprises adjusting the inspection site of a surface of a wafer in the object plane of the multi-beam charged particle beam system and selecting an image setting comprising selecting the first, positive voltage difference VD1 and the second, negative voltage difference VD2. In an example, the first, positive voltage difference VD1 and the second, negative voltage difference VD2 are selected according to a material composition present at the surface of a sample. A material composition can be prior information received from for example CAD files of the semiconductor structures within processed wafers.

In an example, the method further comprises an adjustment step M. During adjustment step M, a setting for a second scanning operation B for charge compensation is confined. The confinement is for example based on an image data obtained in a preceding first or image scanning operation step A.

In an example, the first voltage difference VD1=VS1−VK1 is set between a first sample voltage VS1 applied to the sample and a voltage VK1 of an emitter of primary charged particles within a voltage range about 1 kV, for example VD1=800 V or less, 1 kV, 1.2 kV or 2 kV. In an example, the second voltage difference VD2 is set or confined by setting or confining at least one of a sample voltage VS, a voltage VK of an emitter of primary charged particles, and a voltage VE provided to an electrode within the multi-beam charged particle beam system.

In an example, the method further comprises an image acquisition step I for receiving and storing image data acquired during a first image scanning operation step A. In an example, the method further comprises a collection step C for receiving, analyzing, and storing information acquired during a second scanning operation step B for charge compensation. Such information can for example be a collection of secondary electrons received from regions with positive surface charge, where primary charged particles impinge on the surface during the second scanning operation step B for charge compensation. Thereby, for example regions of positive surface charge are recorded during the second scanning operation. Such information can be used for inspection tasks at similar inspection sites or merged with the image data received during first image scanning operation step A.

In a second aspect, the disclosure provides a multi-beam charged particle beam system comprising an emitter of primary charged particles, connected to an emitter voltage supply for providing an emitter voltage VK to the emitter. The multi-beam charged particle beam system further comprises a sample voltage supply for providing during use a sample voltage VS to a wafer mounted on a sample stage of the multi-beam charged particle beam system. The multi-beam charged particle beam system further comprises a control unit configured for adjusting at least one of the emitter voltage VK or the sample voltage VS. The control unit further comprises a memory storing software instructions and an operation processor for executing the software instructions, when executed causing the multi-beam charged particle beam system to perform any of the method steps according to the first embodiment.

The disclosure is useful, for example, for wafer inspection. In an example, a wafer inspection investigates defects or dimensions of structured photoresist. Photoresist is an insulator and typically shows strong charging effects. With an apparatus and method according to the disclosure, an effect of charging of structured photoresist can be reduced. In an example of a wafer inspection task, structures to be investigated are arrange at a border or edge of a die. For example, a dedicated process control monitor (PCM) can be arranged close to an edge of a die.

In a third aspect, the disclosure provides a method of inspection of a FinFET with a multi-beam charged particle imaging system is provided. The method comprises a first or image scanning operation step A comprising setting a first, positive voltage difference V1 such that primary charged particle beamlets reach the surface of the FinFET at a landing energy LE within a range of landing energies, where a secondary and backscattered electron yield exceeds an incident beam current of primary charged particles, thereby generating image data and generating positive surface charges at least at regions of the insulator of the FinFET. The method further comprises a second scanning operation step B for charge compensation comprising setting a second, negative voltage difference VD2, such that primary charged particle beamlets are reverted in propagation direction before reaching uncharged regions of the surface of the FinFET, such as for example the gate structure. During the second scanning operation step B for charge compensation, primary charged particles however reach the insulator, where the positive surface charges are generated during the first or image scanning operation step A, and a positive surface charge is compensated or balanced. The method further comprises iteratively repeating the first or image scanning operation step A and the second scanning operation step B for charge compensation and computing an image data of the surface by image processing of a plurality of images generated during iteratively repeating the first or image scanning operation step A.

### BRIEF DESCRIPTION OF THE DRAWINGS

Embodiments of the present disclosure will be explained in more detail with reference to drawings, in which:

FIG. 1 is a schematic sectional view of a multi-beam charged particle system according to an embodiment;

FIG. 2 is a further schematic sectional view of a multi-beam charged particle system according to an embodiment;

FIG. 3A-3C illustrates an example of a scanning image acquisition of a surface segment of a wafer;

FIG. 4 illustrates an example of an imaging setting during a first image scanning operation step A;

FIG. 5 illustrates a secondary electron and backscattered electron yield in dependence of landing energy LE or primary charged particles;

FIGS. 6A-6B illustrate examples of imaging settings during a second scanning operation step B in mirror mode;

FIGS. 7A-7D illustrate an example of a method according to the first embodiment;

FIG. 8 illustrates an example of a method according to the first embodiment; and

FIG. 9 illustrates a FinFET structure.

### DETAILED DESCRIPTION

In the exemplary embodiments of the disclosure described below, components similar in function and structure are indicated as far as possible by similar or identical reference numerals. Some array elements, for example the plurality of primary charged particle beamlets, are identified by a reference number. Depending on the context, the same reference number may also identify a single element out of the array elements. Each primary charged particle beamlet (3.1, 3.2, 3.3) is one of the plurality of primary charged particle beamlets (3).

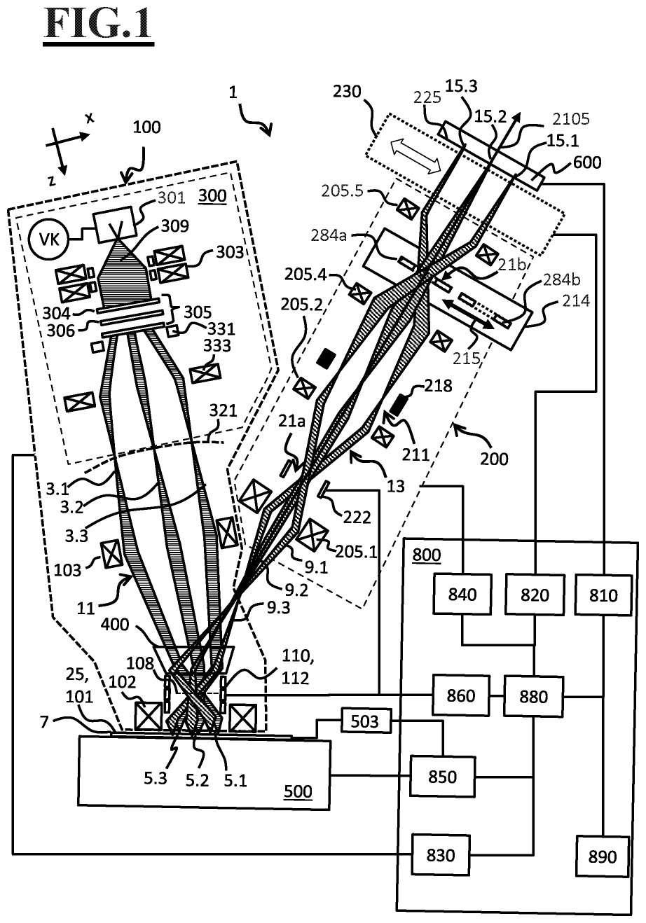

FIG. 1 is a schematic illustration of a multi-beam charged particle imaging system 1 (in short also multi-beam system 1) according to an embodiment. The multi-beam system 1 uses a plurality of charged particle beams for forming an image of an object 7. The multi-beam system 1 generates a plurality of J primary particle beams 3 which strike the object 7 to be examined in order to generate interaction products, e.g. secondary electrons, which emanate from the object 7 and are subsequently detected. The multi-beam system 1 is of the scanning electron microscope (SEM) type, which uses a plurality of primary electron beams 3 which are incident on a surface of the object 7 at a plurality of locations and generate there a plurality of primary electron beam focus spots 5, that are spatially separated from one another. The object 7 to be examined can be of any desired type, e.g., a semiconductor wafer or a semiconductor mask, and can comprise an arrangement of miniaturized elements. The surface 25 of the object 7 is arranged in an object plane 101 of an objective lens 102 of an object irradiation unit 100. The object 7 can be a wafer or a semiconductor mask.

A diameter of the minimal beam spots or focus spots 5 shaped in the object plane 101 can be small. Exemplary values of this diameter are below four nanometers, for example three nm or less. The focusing of the primary charged particle beamlets 3 for shaping the focus spots 5 is carried out by the objective lens system 102. In this case, the objective lens system 102 can comprise a magnetic immersion lens. Further examples of focusing mechanisms are described in the German patent DE 102020125534 B3, the entire content of which is herewith incorporated in the disclosure.

The plurality of focus spots 5 of the primary beamlets 3 form a regular raster arrangement of incidence locations, which are formed in the object plane 101. The number J of primary beamlets 3 may be five, twenty-five, or more. In practice, the number J of beamlets 3, and hence the number of incidence locations or focus spots 5, can be chosen to be significantly greater, such as, for example, J=10×10, J=20×30 or J=100×100. Exemplary values of the pitch P between the incidence locations are 1 micrometer, 10 micrometers, or more, for example 40 micrometers. For sake of simplicity, only three primary beamlets 3.1, 3.2 and 3.3 with corresponding focus points 5.1, 5.2 and 5.3 are shown in FIG. 1.

The primary particles 3 striking the object 7 generate interaction products, e.g. secondary electrons, back-scattered electrons, which emanate from the surface of the object 7, or primary particles that have experienced a reversal of movement for other reasons. The interaction products emanating from the surface of the object 7 are shaped by the objective lens 102 to form secondary electron beamlets 9. For sake of simplicity, through the disclosure, all the interaction products are collectively described as secondary electrons, forming secondary electron beamlets 9.

The multi-beam system 1 provides a detection beam path 13 for guiding the plurality of secondary particle beamlets 9 to a secondary electron imaging system or detection unit 200. The secondary electron imaging system 200 comprises several electron-optical lenses 205.1 to 205.5 for directing the secondary particle beams 9 towards a spatially resolving particle detector 600. The detector 600 is arranged in the image plane 225. The detector 600 comprises a plurality of detection elements. Detection elements can for example be diodes such as PMDs, or CMOS detection elements, provided with electron-to-light conversion elements, or can be formed as direct electron detection elements.

In an example, the detector 600 comprises an electron-to-light conversion element, such as a scintillator plate, by which secondary electrons are converted into light, and a plurality of light detection elements. The combination of the electron-to-light conversion element and the plurality of light detection elements hereby form together a plurality of electron detection elements. The detector or image sensor 600 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is hereby incorporated by reference.

The imaging with the secondary electron imaging system 200 is strongly magnifying such that both the raster pitch of the primary beams on the wafer surface and the size and shape of focal points of the primary beamlets 3 are imaged in much magnified fashion. By way of example, a magnification is between 100× and 300× such that one nm on the wafer surface is imaged enlarged to between 100 nm and 300 nm. In an example, an image field of a multi-beam system with for example 100 μm diameter is enlarged to approximately 30 mm.

The primary particle beams 3 are generated in a beam generation apparatus 300 comprising at least one charged particle emitter 301, at least one collimation lens 303, a multi-aperture arrangement 305 and a first field lens 331 and a second field lens 333. The charged particle emitter 301 is connected to a voltage supply for providing an emitter voltage VK to the emitter 301 and generates at least one diverging charged particle beam 309, which is at least substantially collimated by the at least one collimation lens 303, and which illuminates the multi-aperture arrangement 305. The multi-aperture arrangement 305 comprises at least one first multi-aperture or filter plate 304, which has a plurality of J openings formed therein in a first raster arrangement. Particles of the illuminating particle beam 309 pass through the J apertures or openings of the first multi-aperture plate 304 and form the plurality J of primary beamlets 3. Particles of the illuminating beam 309 which strike the first aperture plate 304 are absorbed by the latter and do not contribute to the formation of the primary beamlets 3. A multi-aperture arrangement 305 usually has at least a further multi-aperture plate 306, for example a lens array, a stigmator array or an array of deflection elements. In this example, the particle beam 309 is perfectly collimated by collimation lens 303. However, it is also possible to design the multi-aperture arrangement 305 for a diverging or converging incident particle beam 309.

Together with the field lens 331 and a second field lens 333, the multi-aperture arrangement 305 focuses each of the primary beamlets 3 in such a way that focal points are formed in an intermediate image surface 321. Alternatively, the beam foci and the intermediate image surface 321 can be virtual. The intermediate image surface 321 can be curved and tilted to pre-compensate a field curvature and image plane tilt of the charged particle imaging system arranged downstream of the intermediate image surface 321.

The at least one field lens 103 and the objective lens 102 provide a first imaging particle optical unit for imaging the surface 321, in which the beam foci are formed, onto the object plane 101 such that a second raster configuration of focus spots 5 of the primary beamlets is formed there. Typically, the surface 25 of the object 7 is arranged in the object plane 101, and the focal points 5 are correspondingly formed on the object surface 25. The plurality of primary beamlets 3 form a crossover point 108, in the vicinity of which a first scanning deflector 110 is arranged. The first scanning deflector 110 is used to deflect the plurality of primary beamlets 3 collectively and synchronously such that the plurality of focus spots 5 are moved simultaneously over the surface 25 of the object 7. The first scanning deflector 110 is driven by a scanning control unit 860 such that in an inspection mode of operation, a plurality of two-dimensional image data of the surface is acquired. Additionally, the multi-beam system 1 can comprise further static deflectors and multipole elements 112 configured to adjust the position and beam shapes of the plurality of the primary beamlets 3.

The objective lens 102 and the projection lenses 205 provide a secondary electron imaging system 200 for imaging the object plane 101 onto the detection plane 225. The objective lens 102 is thus a lens or a lens system that is part of both the first and the second particle optical unit, while the field lenses 103, 331 and 333 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary electron beamlets 9 transmit during use the first deflection scanner 110 in opposite direction and the scanning movement of the secondary beamlets 9 is partially compensated. The secondary electrons have typically a different kinetic energy compared to the primary electrons. Therefore, the scanning movement of the moving irradiation positions is only partially compensated. The secondary electron imaging system 200 therefore comprises the second, collective beam deflector 222 which is arranged in the vicinity of a crossover plane or pupil plane 21a of the secondary electron beamlets 9. The second, collective beam deflector 222 is operated synchronously with the first beam deflector 110 and compensates during use a beam deflection of the secondary electron beamlets 9 such that the focus points 15 of the secondary beamlets 9 remain at constant position on the detection plane 225. Thereby, each focus points 15 of each individual secondary beamlet 9 is kept within the area of a set of detection elements, which is assigned to the individual secondary beamlet 9.

Together with the objective lens 102, the lenses 205 serve to focus the secondary beams 9 on the spatially resolving detector 600 and, in the process, compensate the imaging scale and the twist of the plurality of secondary electron beamlets 9 as a result of a magnetic lens such that a third raster arrangement of the focal points 15 of the plurality of secondary electron beamlets 9 remains constant on the detector plane 225. The electron-optical lenses 205.1 to 205.5 are shown as magneto-optical elements but are not limited to magneto-optical elements and can comprise also electro-static lens elements or stigmators. The secondary electron imaging system 200 further comprises an exchangeable contrast aperture 284a, 284b, mounted on an exchange mechanism 214 at a pupil plane 21 of the secondary electron imaging system 200. With an exchange mechanism 215, different aperture stops 284a or 284b can be positioned in the second pupil plane 21b and aligned with respect to the optical axis 2105 of the secondary electron imaging system 200.

Further information relating to such multi-beam particle beam systems and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The multi-beam charged particle imaging system 1 furthermore comprises a control unit 800 configured both for controlling the individual particle optical components of the multiple particle beam system and for evaluating and analyzing the signals obtained by the detector 600. In this case, the control or controller unit 800 can be constructed from a plurality of individual electronic computers or electronic components. By way of example, the control unit 800 comprises a control operation processor 880, a control module 840 for the control of the electron-optical elements of the secondary electron imaging system 200 and a control module 830 for the control of the electron-optical elements of the primary beamlet generation unit 100. The control unit 800 further comprises a stage control module 850 for positioning the sample surface 25 or sample 7 by stage 500 within the object plane 101. The control unit 800 further comprises a control module to adjust a sample voltage VS, which is connected to a module 503 for supplying the sample voltage VS to the sample 7, the sample voltage VS also being referred to as extraction voltage. Thereby, during use, an extraction field is generated between the objective 102 and the surface 25 of the object 7. During use, the extraction field decelerates the primary charged particles of the primary beamlets 3 before the sample surface 25 is reached and generates an additional focusing effect on the plurality of primary beamlets 3. At the same time, the extraction field serves during use to accelerate the secondary particles out of the surface 25 of the object 7.

Further, the control unit 800 comprises the scanning control module 860. During an inspection mode of operation, a plurality of focus points 15 of secondary electron beamlets is formed in the detection plane 225, and a plurality of signals is recorded during scanning operation of the primary beamlets 3 over the surface 25 of the sample 7. The detector 600 comprises a plurality of sets of detection elements with one set of detection elements for each secondary electron beamlet 9. During use, each set of detection elements is configured to record the intensity signal of the assigned secondary electron beamlet 9. The plurality of intensity signals for the plurality of secondary electron beamlets 9 is transferred to the image data acquisition unit 810, where the image data is processed and stored in memory 890. The setup of the secondary electron optical imaging system 200, the detector 600, and the assignment of the sets of detection elements to the focus spots 15 of the secondary electron beamlets 9 is initially determined and stored in the memory 890 of the control unit 800 of the multi-beam charged particle imaging system 1.

According to the example of FIG. 1, the multi-beam charged particle imaging system 1 further comprises a retractable monitoring system 230, which can be inserted into the secondary electron beam path in front of the detection plane 225. The monitoring system 230 comprises further imaging elements and a high-resolution detector. The monitoring system 230 is connected to a monitoring control unit 820.

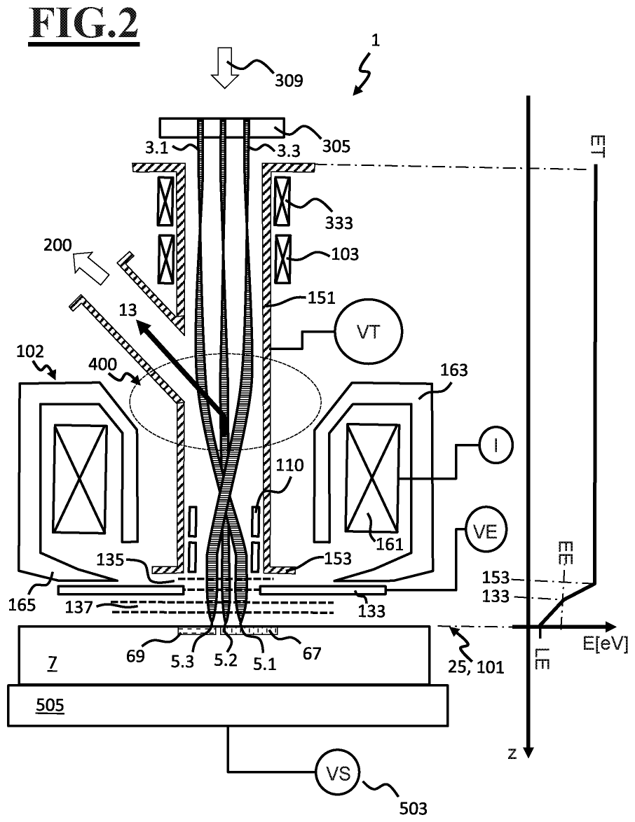

FIG. 2 illustrates further details of a multi-beam charged particle beam system 1 according to an embodiment. Same reference numbers are used as in FIG. 1 and reference is also made to the description of FIG. 1. From a collimated electron beam 309, a plurality of primary charged particle beamlets 3 is generated by the multi-aperture arrangement 305. For simplicity, again only 3 beamlets 3.1 to 3.3 are shown. A beam tube 151 is provided downstream of the multi-aperture arrangement 305, the beam tube 151 being connected to a voltage supply with the first or tube voltage VT. From the entrance of a beam tube 151, the plurality of primary charged particle beamlets 3 is at a constant kinetic energy ET until the exit opening 153 of the beam tube 151 (see energy plot on the right side of FIG. 2). The kinetic energy ET of the primary charged particle beamlets 3 is for example 20 KeV, 30 keV or more.

The plurality of primary charged particle beamlets 3 are imaged and focus points 5.1 to 5.3 are formed in an image plane 101 by field lenses 333 and 103, and by objective lens 102. The objective lens 102 is of the type of a magnetic lens with a coil 161 and a pole shoe 163 with a lower pole shoe segment 165, forming an axial gap for the magnetic field. A current I is provided during use to the coil 161 to generate the focusing magnetic field (not shown). Other types of magnetic lenses are possible as well, for example radial gap lenses for generation an immersion lens field, or magnetic lenses with several coils and pole shoes. Upstream or partially integrated in the objective lens 102, a beam divider 400 is arranged, configured to separate the secondary electrons along secondary electron beam path 13 to detector unit 200. Below the lower pole shoe segment 165, an electrode 133 is provided, connected to a voltage supply for providing a second voltage VE to the electrode. In the example shown, the electrode 133 is provided as separate electrode.

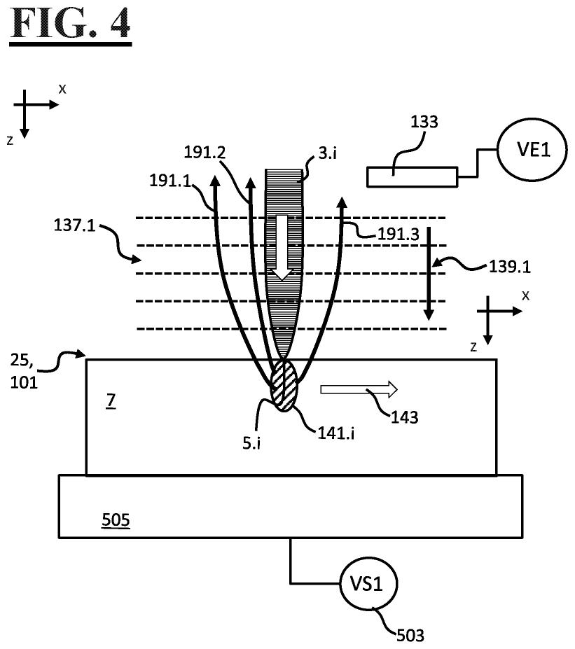

After leaving the beam tube 151, the primary charged particle beamlets 3 are decelerated from kinetic energy ET to a second kinetic energy EE. The voltage difference between VT and VE is responsible for the generation of a first electric field 135, illustrated in FIG. 2 with the equipotential lines of the first electric field 135. The first electrical field vectors are almost parallel to the propagation direction of the primary charged particle beamlets 3 and generate a decelerating force to the primary charged particles. The first voltage VE is typically adjusted such that the second kinetic energy EE is in a range below 5 keV, below 3 keV or even below 2 keV. Via sample voltage supply 503, a third sample voltage VS is provided to a sample mounting platform 505 for holding and contacting during use a wafer 7. At the surface 25 of the wafer 7, a first material composition 67 is arranged under a first set of primary charged particle beamlets 3.1 and 3.2, and a second material composition 69 is arranged under a second set of primary charged particle beamlets comprising primary charged particle beamlet 3.3. According to the voltage difference between VS and VE, a second electrical field 137 is generated, which is almost parallel to the propagation direction of the primary charged particle beamlets 3 and generates a decelerating force to the primary charged particles. For example, the third or sample voltage VS is adjusted such that the third kinetic energy LE is adjusted to a kinetic landing energy in a range below 800 eV, below 300 eV or even below 100 eV. The first electrical field 135 also forms an accelerating field on secondary electrons extracted from the wafer 7. The second electrical field 137 forms an extraction field for extracting and accelerating secondary electrons from the wafer 7. The second field 137 is therefore also called the extraction field 137. The image formation and extraction mechanism according to a first embodiment is further illustrated in FIG. 4. A primary charged particle beamlet 3.i is focused during an image scanning operation step to focus point 5.i and impinges on the surface 25 of wafer 7 and forms an interaction volume 141.i within the wafer 7. For example, during the operation at the low energy levels below 1 keV, the interaction volume 141.i has a small extension below 5 nm. During use, a parallel extraction field 137 is generated, with electrical field vectors 139 being perpendicular to the wafer surface 25. The extraction field 137 (illustrated by equipotential lines) extracts and accelerates secondary electrons generated in the interaction volume 141.i along electron trajectories (some example of electron trajectories 191.1 to 191.3 are shown) in opposite propagation direction to the primary electron beam direction. After collecting sufficient secondary electrons during the dwell time of about 50 ns, the primary beamlet 3.i is moved by scanning deflector (not shown) along scanning direction 143 to the next image pixel position. Thereby, image data of a surface of a sample is acquired.

The example illustrated in FIG. 2 shows a multi-beam charged particle beam system 1 with a two-stage deceleration field 135 and 137 and an additional electrode 133. In another example only a single decelerating or extraction field 137 is generated between exit aperture 153 of the beam tube 151 and a sample 7 mounted on the sample platform 505. In this case, the exit aperture 153 of the beam tube 151 has the role of the electrode 133 for the extraction field 137.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scanning operation step, the control unit 800 is configured to trigger the image sensor 600 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

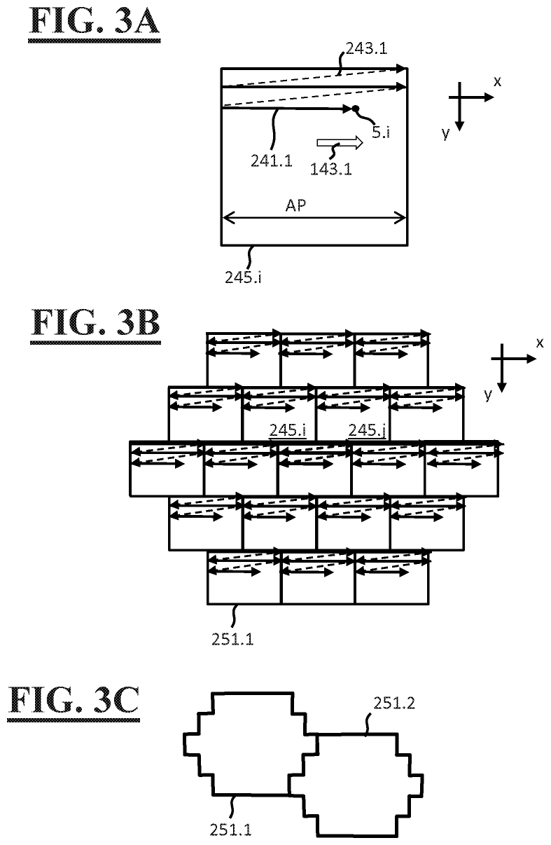

FIGS. 3A-3C illustrate a scanning operation of the plurality of primary charged particle beamlets 3 during an image acquisition. The scanning operation control module 860 is configured to provide during use a scanning signal to scanning deflector 110. Thereby, each primary charged particle beamlet 3 is deflected by the collective multi-beam raster scanner 110 such that the corresponding focus spot 5.i is scanned over an image patch 245.i of a single beamlet (FIG. 3A). Each image patch 245.i has a diameter AP of for example 8 μm to 10 μm. The scanning operation comprises a scanning of a plurality of parallel image scanning lines 241 along scanning direction 143.1 for image acquisition. At the end of each image scanning line 241, each beamlet 3 is moved back to the starting position of a next scanning line, which is also called “flyback” 243. During image acquisition along image scanning lines 241, the scanning operation is controlled to achieve a dwell time of about 50 ns at each image point, with for example 8000 images points per image scanning line 241. The time for flyback 243 can be much shorter, for example 20 ns in total. FIG. 3B shows the parallel operation of a plurality of primary charged particle beamlets 3 to acquire an image of a surface segment 251 of a wafer surface, consisting of a plurality of image patches 245. FIG. 3C shows two adjacent surface segments 251.1 and 251.2, each comprising a plurality of patches corresponding to the plurality of primary charged particle beamlets 3.

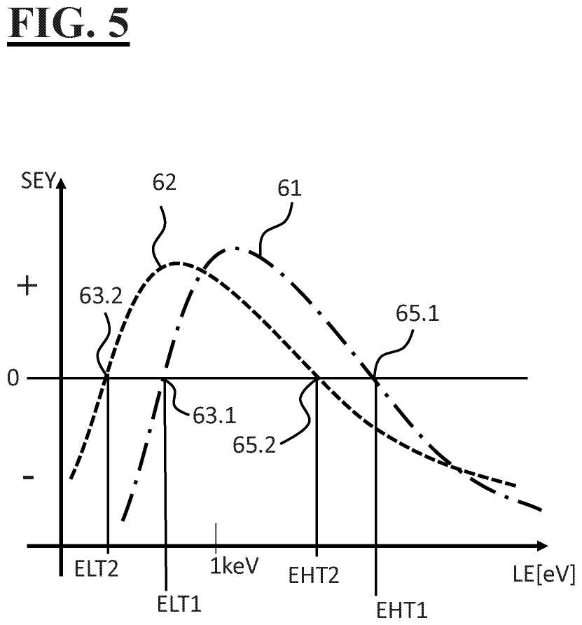

The backscattered and secondary electron yield SEY is a function of the primary beam energy. FIG. 5 illustrates two examples of residual charging curves for different material compositions in dependence on the primary charged particle energy. The residual charging of a first material composition with is illustrated with reference number 61. The residual charging curve 61 show areas in which a sample is positively charged between the two kinetic energies ELT1 and EHT1, i.e. more secondary and backscattered electrons leave the sample compared to the deposited charge by the primary electrons. The residual charging curve 61 show areas where a sample is negatively charged at energies below ELT1 and above EHT1, i.e. less secondary or backscattered electrons leave the sample compared to the deposited charge, leading to a negative charge accumulation in the sample. The residual charge of a second material composition is illustrated with reference number 62, with the two kinetic energies ELT2 and EHT2. At the transition energies ELT and EHT, for each material composition, respectively, a sample charging is minimized. A first minimum sample charging is achieved at a low kinetic energy ELT, corresponding to the low energy transition point ELT with no sample charging. A low energy transition point ELT is depending on the material composition and is about below 800 eV, below 500 eV or even less. For example, for typical materials such as Cu, W, Al, Si, SiO2 or SiN2, comprised in semiconductor wafers, the low energy transition point is between 80 eV and 250 eV. A second minimum sample charging is achieved at a higher kinetic energy EHT, corresponding to the high energy transition point EHT with no sample charging. The high energy transition point EHT is depending on the material composition and is typically above 1 keV. For example, the high energy transition point EHT of copper (Cu) or tungsten (W) is above 2 keV, where an imaging with high resolution is not possible anymore. A low kinetic energy transition point ELT is sometimes also called the instable neutral point 63. A high kinetic energy transition point EHT is sometimes also called the stable neutral point 65. The backscattered and secondary electron yield SEY and the transition points ELT and EHT are however further depending on topographic effects. By proper adjustment of the extraction field generated by voltage supply 503, a residual charging of a selected material composition can be minimized.

According to the first embodiment, a landing energy LE of primary charged particles is selected and adjusted such that, for each primary charged particle beamlet, a secondary and backscattered electron yield exceeds a beam current of the primary charged particle beamlet, such that a high image contrast and low noise level is achieved. In addition, with the landing energy selected between ELT and EHT of the majority of materials present at the surface 25 at the inspection site of the sample 7, a positive surface charge is generated at least at some areas of the surface 25 of the sample 7.

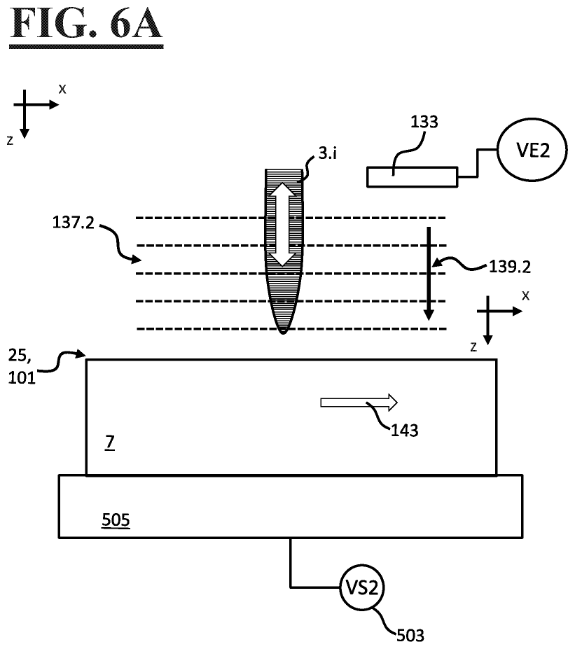

FIGS. 6A-6B illustrate a reversal of a primary electron beamlet 3.i in a second scanning operation step for charge compensation. In FIG. 6A, an extraction field strength 139.2 of the extraction field 137.2 is increased by sample voltage VS2 provided by voltage supply unit 503. Therefore, primary electrons do not have sufficient kinetic energy to reach the sample surface 25 and are reflected in reverse direction. This mode of operation is sometimes also called mirror mode. During operation in mirror mode, no charging of the wafer surface is achieved.

In an example illustrated in FIG. 6B, the beam landing energy LE is defined by the difference of the emitter voltage VK and the sample voltage supply VS. In the example of FIG. 6B, the tube voltage VT is set to ground level. The landing energy or operation in mirror mode can be adjusted by either changing the emitter voltage VK or the sample voltage VS. If the absolute value of the sample voltage VS2 exceeds the emitter voltage VK2 by few Volt, electrons may not reach the surface 25 of a wafer 7. For example, the emitter voltage VK2 is set to −30 kV for a kinetic beam energy of 30 keV, and the sample voltage is set to VS2=−30005 V with a voltage difference of only 5 V. Thereby, electrons of electron beamlet 3.1 may not reach sample surface 25. For example, the emitter voltage VK2 is set to −29995 kV for a kinetic beam energy of 29995 eV, and the sample voltage is set to VS2=−30 kV with a voltage difference of only 5 V. Thereby, electrons of electron beamlet 3.1 may not reach sample surface 25.

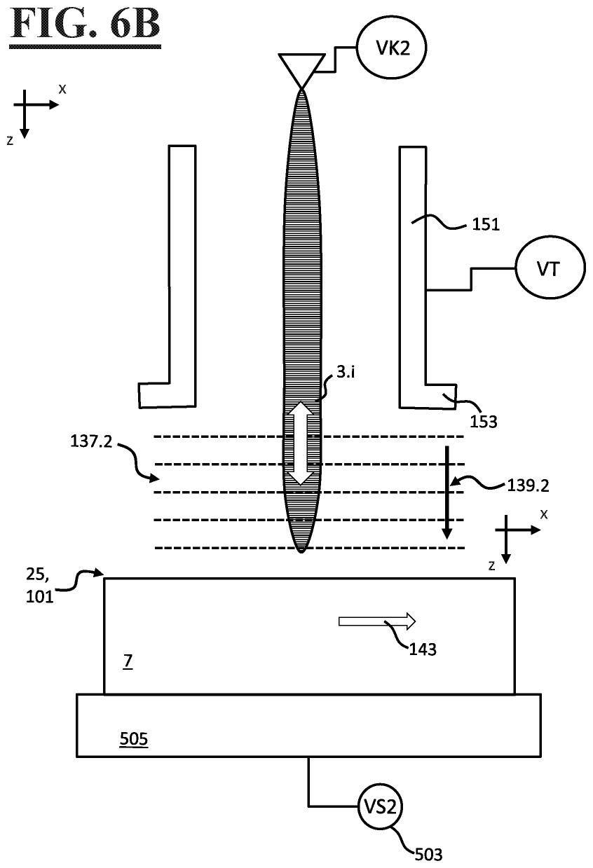

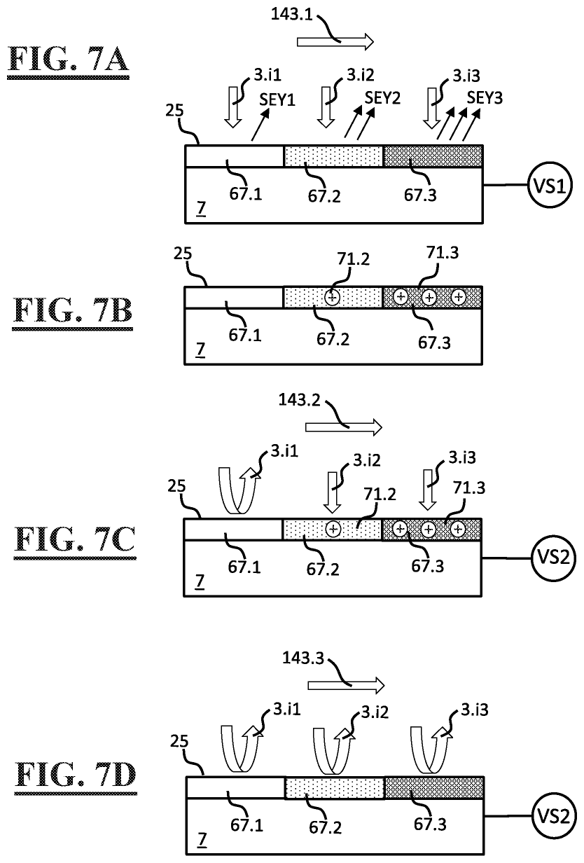

According to the first embodiment, the kinetic beam energy or field strength of the extraction field is adjusted such that in presence of charged regions of the wafer surface, either a discharging or a reversal of primary electrons is achieved. Thereby, charging of different material compositions on a surface of a wafer is compensated. An example is illustrated in FIGS. 7A-7D. FIG. 7A shows a first step of an image acquisition along a scan line 143.1 with different areas 67.1 to 67.3 and a first sample voltage VS1. In this example, the kinetic energy of the primary electron beamlets 3 is adjusted between the low energy and high energy transition points, such that a positive surface charging in some material compositions is achieved. The primary beamlet 3.i is first scanned over scanning positions 3.i1 at the first material composition 67.1 with a low secondary electron emission or yield SEY1, and no charge is accumulated in the first material composition 67.1. The primary beamlet 3.i is then scanned over scanning positions 3.i2 at the second material composition 67.2 with a medium secondary electron emission or yield SEY2, and a moderate positive surface charge 71.2 is accumulated at the surface of the second material composition 67.2. The primary beamlet 3.i is then scanned over scanning positions 3.i3 at the third material composition 67.3 with a high secondary electron emission or yield SEY3, and a large positive surface charge 71.3 is accumulated at the surface of the second material composition 67.3 (see FIG. 7B).

In a second scan 143.2, illustrated in FIG. 7C, the kinetic energy of primary electrons is adjusted to a mirror mode operation with sample voltage VS2. Therefore, at first scanning position 3.i1, with no positive surface charge, the primary beamlet 3.i is reversed. At the second and third positions 3.i 2 and 3.i3, however, the primary beamlet reaches the sample with low kinetic energy and primary electrons are absorbed and compensate the positive local surface or volume charges 71.2 and 71.3 accumulated by the second and third material compositions 67.2 and 67.3. After charges are balanced, the primary beamlet 3.i is reversed at all positions on the surface of the wafer 7, including at scanning positions 3.i2 and 3.i3 at material compositions 67.2 and 67.3 (FIG. 7D). Image acquisition is then continued with the next scanning line. Thereby, charges are iteratively removed before for example each next or after each 10^{th} scanning line and high precision images are obtained, absent of any deteriorations from charging effects.

With the method according to the first embodiment illustrated in FIGS. 7A-7D, a positive sample charging is compensated or balanced by an operation of the multi-beam charged particle microscope in mirror mode operation. In a first scanning operation, a first landing energy of primary charged particles is adjusted such that at specific material compositions, positive surface charges 71 are generated. During the first scanning operation, secondary electrons are generated and collected by detection unit 200 and image lines are recorded by imaging control module 810. In a second scanning operation, a second energy of primary charged particles is adjusted such that the primary beamlets are reflected at uncharged sections or the sample surface 25. The second energy is for example adjusted via sample voltage VS in a manner that accumulated positive charges 71 at the surface 27 provide sufficient additional acceleration to the surface 25 of the sample such that primary charged particles reach the sample surface at low kinetic energy, for example below the ELT, such that the majority of the primary charged particles is absorbed without the generation of many secondary electrons. As an effect, positive surface charges 71.2 and 71.3 are removed during the second scanning operation.

First and second scanning operations can by iteratively repeated. In an example, first and second scanning operations are iteratively repeated for each scanning line 241 (see FIGS. 3A-3C). In an example, the second scanning operation is performed instead or during a fly-back operation 243.

In an example, the second scanning operation at the second energy of primary charged particles is performed after acquisition of an image segment 251.1. Thereby, residual charging is removed before an image of an adjacent image segment 251.2 is acquired.

In an example, during a second scanning operation, further properties of the primary charged particle beamlets 3 are changed in addition to the change to the second energy via VS2. For example, a focus position is changed such that the focus points 5 of primary charged particle beamlets 3 are not formed at the surface 25 of the sample 7. Thereby, a coarser sampling of large distance from line to line can be adjusted and a second scanning operation can be performed within a reduced time interval. For example, positions of surface segments with charging material compositions are determined from an image or from prior information, and a second scanning operation is limited to the regions of positive surface charge 71.2 or 71.3. Thereby, a throughput is increased.

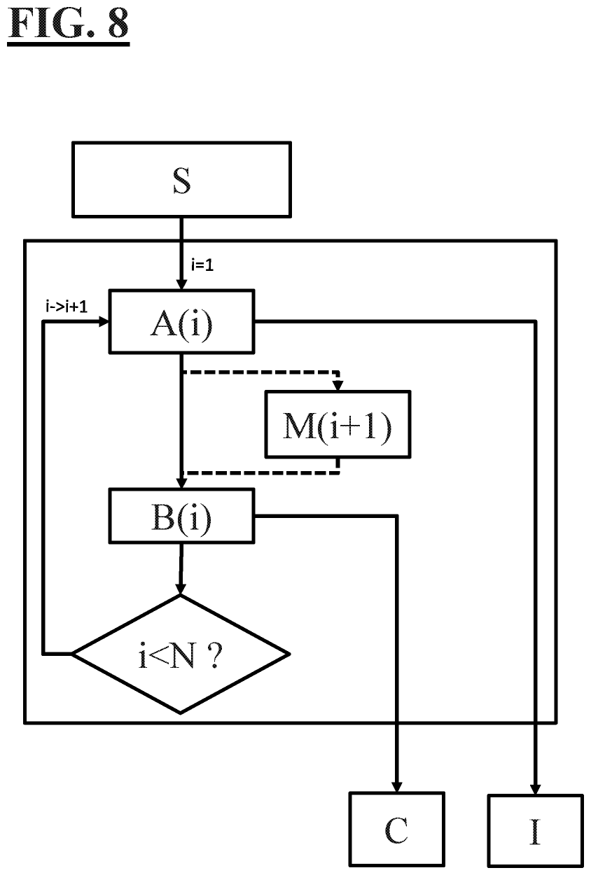

A method according to the first embodiment is further described in FIG. 8. In setting adjustment step S, an inspection site on a surface 25 of a wafer 7 is adjusted in the object plane 101 of the multi-beam charged particle beam system 1 and an image setting is selected. For example, a landing energy LE of primary electrons is selected for a large secondary electron yield SEY at least for some material compositions present at the inspection site of a sample surface. Thereby, a large image contrast with low image noise is achieved. Generally, a landing energy LE is selected between a low energy transition energy ELT and a high energy transition energy EHT (see FIG. 5). For example, a landing energy LE is selected to achieve a large secondary electron yield SEY for an insulating material composition such as silicon dioxide of high-k dielectrics, where charges are accumulated. The image setting comprises setting a first, positive voltage difference VD1 such that primary charged particle beamlets reach the sample surface (25) at a landing energy LE within a range of landing energies, where a secondary and backscattered electron yield exceeds an incident beam current of primary charged particles. Optionally, prior information about the material composition of the surface 25 of the wafer 7 at the inspection position is loaded for example from a CAD file.

In first or image scanning operation step A, a first or image scanning operation is performed. During the first or image scanning operation A(1), a first image setting is adjusted. As part of the first image setting, a landing energy LE of primary electrons is adjusted to the selected landing energy selected in step S via voltages VK1, VE1 and VS1 to achieve a large SEY (see FIG. 5). For example, VS1 is set to VS1=(ET−LE)/e, for example with primary electrons within the beam tube 151 at ET=30 keV and VS1=−29 kV, a landing energy of LE=1 keV is adjusted, at which a large secondary electron yield is achievable (see FIG. 5). For example, with emitter potential VK1=−30kV and VS1=−29 kV, a landing energy of 1 keV is adjusted, at which a large secondary electron yield is achievable. Generally, with a positive first voltage difference VD1=VS1−VK1, electrons reach the surface 25 of sample 7 with a landing energy LE=e*VD.

In an example, the first scanning operation comprises a first set of image scanning lines 241, each set of image scanning lines 241 comprises for example one, two, ten or more scanning lines 241 of each image patch 245 of each primary charged particle beamlet.

In optional adjustment step M, a confined setting for a subsequent second scanning operation B for charge compensation is adjusted. In an example, the adjustment comprises an assessment of the image information acquired during the previous image scanning operation A(i) and an individual adjustment of a line scanning operation for charge compensation B(i) according to the previous image scanning operation A(i).

In second scanning operation step B for charge compensation, a second scanning operation for charge compensation is performed. A setting of the multi-beam charged particle beam system 1 is adjusted to a compensation setting. During the compensation setting, at least one of emitter potential VK2, electrode voltage VE2 or sample voltage VS2 are adjusted such that primary particles are reversed at uncharged segments or segments with negative surface charge of the surface 25 (see FIG. 6). For example, with primary electrons within the beam tube 151 at a kinetic energy of ET=30 keV and VS2=−30.001 kV, primary electrons are reversed in propagation direction and do not reach the sample. With the negative, second voltage difference VD2=VS2−ET/e, here VD2=−1V, a threshold for a minimum desired charging at a surface 25 of a sample 7 is defined. For example, with emitter potential VK1=−30 kV and VS2=−30003V, a mirror mode is adjusted with a negative second voltage difference of VD2=VS2−VK1=−3V. For example, with emitter potential VK2=−29995V and VS2=−30000V, a mirror mode is adjusted with a voltage difference of VD2=VS2−VK2=−5V. With the second voltage difference VD2, a threshold for a minimum desired charging at a surface 25 of a sample 7 is defined, such that primary electrons only reach surface regions, where the positive surface charges are generated and a local voltage U=Q/C exceeds the voltage difference VD2. The absolute value of VD2, |VD2|, can be 100V, 50V, 10V, or even less, for example 5V or 1V.

In an example, the second scanning operation comprises a second set of scanning lines 241, for example one, two, ten or more scanning lines 241 of each image patch 245 of each primary charged particle beamlet. In an example, the second scanning operation is performed during a fly-back 243 of each primary charged particle beamlet 3. Thereby, charging is compensated during image acquisition.

In an example, an inspection task comprises several adjacent surface segments 251.1, 251.2 (see FIG. 3c). After image acquisition of a first surface segment 251.1, a surface charge can be generated at first surface segment 251.1. Thereby, a second image acquisition of the adjacent surface segment 251.2 can be deteriorated. According to the method, the second scanning operation step B for charge compensation is performed at the first surface segment 251.1, before a wafer is moved by wafer stage 500 to a second surface segment 251.2 adjacent to the surface segment 251.1. Thereby, an influence of a surface charge on an adjacent pre-exposed surface segment to a second or subsequent surface segment is reduced. Thereby, a charging of a surface segment is reduced before a subsequent scanning image acquisition step of an adjacent surface segment is performed.

In an example, the second scanning operation is limited to a scanning range at a border or edge of a surface segment 251.1 (see FIGS. 3A-3C). Thereby, charging is compensated or reduced for a subsequent acquisition of an image of an adjacent surface segment 251.2.

During mirror mode, reflected primary electrons provide to a constant detection signal at the image sensor of the detection unit. In an example, the second scanning operation is repeated until a secondary electron signal is minimal and the signal changes from the signal of secondary electrons to the signal of mirrored primary electrons. Secondary electrons are only emitted from surface areas with positive charges, where the primary electrons may impinge on the sample surface and secondary electrons are generated. In mirror mode, with no surface areas with positive charge, no secondary electrons are excited, and a constant detection signal is received.

First or image scanning operation step A(i), second scanning operation step B(i) for charge compensation and the optional adjustment step M(i) are repeated for a predetermined number N of iterations, for example each scanning line (e.g. N=8000), each set of ten scanning lines (N=800), or each frame (N=1) of an image of a surface segment 251.

Each image data string generated during each first or image scanning operation step A(i) is received and stored in image acquisition step I. Image acquisition step I comprise image processing operations selected from a group of operations including image stitching, image filtering, object detection, and defect detection.

In optional collection step C, image information acquired during second scanning operation step B for charge compensation is collected and analyzed. For example, image information acquired during second scanning operation step B in mirror mode is utilized to identify regions with strong charging properties. In an example, such information of collection step C is used for charge compensation at subsequent inspection sites.

Surface charges can be generated during a first image acquisition, or surface charges can present at a surface of a sample even before a first image acquisition. The method is however not limited to surface charges generated during a first image acquisition step A. In an example, the second scanning operation step B for charge compensation is performed before or previous to a first or image scanning operation step A, and a charge present at a surface of a sample is reduced or removed before an image acquisition. The method is generally comprising a scanning operation step B for charge compensation. The scanning operation step for charge compensation B comprises setting a negative voltage difference VD2 to a sample mounted to the sample stage, such that primary charged particle beamlets are reverted in propagation direction before reaching uncharged regions of the surface of the sample. Such mode of operation is also called mirror mode. The second, negative voltage difference VD2 can be adjusted such that primary charged particles only reach the surface of a sample at the regions, where the positive surface charges are present. Thereby, positive surface charges are removed, and a charging is at least partially compensated.

In an example, a wafer surface comprises surface areas where negative charge is accumulated during imaging. Such negative charge cannot be compensated by the second scanning operation for charge compensation. In such an example, a further scanning operation can be added with a landing energy LE adjusted to a material composition such that also at surface areas with negative charges, a secondary and backscattered electron yield exceeds an incident current of an electron beamlet, such that at surface areas with negative charges, the negative charges are compensated and for example a positive surface charging is achieved. Such a third scanning operation can be inserted before each second scanning operation B(i) for charge compensation of positive charges.

A multi-beam charged particle beam system 1 according to the second embodiment comprises the control operation processor 880 and software code installed in memory 890, which, when executed by control operation processor 880, controls the multi-beam charged particle beam system 1 to execute a method according to the first embodiment.

With the multi-beam charged particle beam system 1 according to the second embodiment and the method according the first embodiment, a distributed surface charge generated during a first image scanning operation is compensated by a second scanning operation for charge compensation. In some examples, charging effects appear at specific structures or features at limited areas of a surface of a sample such as a wafer. For example, a wafer typically comprises repetitive structures (dies), which are separated by small gaps. Charging effects typically accumulate at those gaps or borders of dies. With the method according to the first embodiment, charging effects at borders or edges of dies generated during a first image scan are compensated by a second scanning operation in mirror mode for charge compensation.

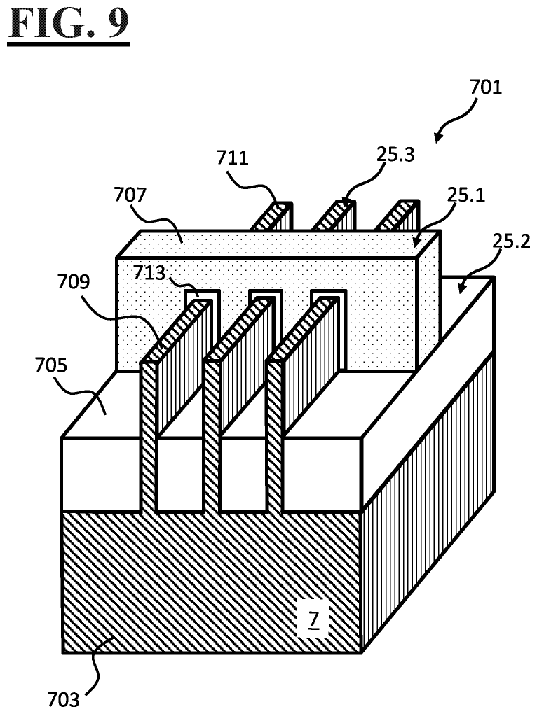

The disclosure is useful for wafer inspection. In an example, a task of a wafer inspection is the investigation of defects or dimensions of structured photoresist. Photoresist is an insulator and shows strong charging effects. With an apparatus and method according to one of the embodiments, an effect of charging of structured photoresist can be minimized. In an example of a wafer inspection task, dimensions of structures of FinFETs are to be measured. An example of a FinFET is illustrated in FIG. 9. A wafer 7 comprising FinFETs 701 comprises a surface topography with a first surface 25.1 of a gate structure 707 comprising polysilicon, a second surface 25.2 of insulator layer 705 comprising silicon dioxide, and a third surface 25.3 of FIN structure comprising source 709 and drain 711, made from bulk silicon material 703 of the wafer 7. Soure 709 and drain 711 are isolated from gate 707 by high-k dielectric coating 713, made e.g. from Tantalum pentoxide, Hafnium silicate, Zirconium silicate, Hafnium dioxide, or Zirconium dioxide. Polysilicon gate 707, insulating layer 705 and high-k dielectric coating 713 may build up charges during imaging, which may cause that source 709 and drain 711 are almost invisible during electron beam imaging. an apparatus and method according to one of the embodiments, an effect of charging of FinFETS can be mitigated and for example dimensions of FIN structures comprising source 709 and drain 711 can be measured with high accuracy. In an example of a wafer inspection task, structures to be investigated are arrange at a border or edge of a die. For example, a dedicated process control monitor (PCM) can be arranged close to an edge of a die. With an apparatus and method according to one of the embodiments, a charging of a gap surface between two dies or at an edge of a die can be avoided, and an effect of charging can be avoided.

The disclosure is further described by following clauses:

Clause 1: A method of operating a multi-beam charged particle beam system (1), comprising
a first or image scanning operation step A comprising setting a first, positive voltage difference VD1 such that primary charged particle beamlets reach the sample surface (25) at a landing energy LE within a range of landing energies, where a secondary and backscattered electron yield exceeds an incident beam current of primary charged particles, thereby generating image data and generating positive surface charges at least at regions of the surface (25) of the sample (7),
a second scanning operation step B for charge compensation comprising setting a second, negative voltage difference VD2, such that primary charged particle beamlets (3) are reverted in propagation direction before reaching uncharged regions of the surface (25) of the sample (7), and reach the surface (25) of a sample (7) at the regions, where the positive surface charges are generated during the first or image scanning operation step A.

Clause 2: The method of clause 1, wherein the absolute value of the second, negative voltage difference VD2 is less than 100V, for example 50V, for example 10V or 5V, for example 1V.

Clause 3: The method of clause 1 or 2, further comprising iteratively repeating the first or image scanning operation step A and the second scanning operation step B for charge compensation. Clause 4: The method of clause 3, wherein the first or image scanning operation step A and the second scanning operation step B for charge compensation are iteratively repeated each sequence of scanning lines (241), wherein the sequence of scanning lines (241) comprises one, two, ten or more scanning lines (241). Clause 5: The method of clause 3 or 4, wherein the second scanning operation step B for charge compensation is performed during a fly-back (243) of each primary charged particle beamlet (3). Clause 6: The method according to any of the clauses 1 to 4, comprising acquiring during the first or image scanning operation step A an image of a surface segment (251) of a wafer surface (25), and at least partially compensating a surface charge at the surface segment (251) during second scanning operation step B for charge compensation. Clause 7: The method according to clause 6, wherein the second scanning operation step B for charge compensation is limited to a scanning range at a border or edge of a surface segment (251). Clause 8: The method of any of the clauses 1 to 7, further comprising a setting adjustment step S, comprising adjusting the inspection site of a surface (25) of a wafer (7) in the object plane (101) of the multi-beam charged particle beam system (1) and selecting an image setting comprising selecting the first, positive voltage difference VD1 and the second, negative voltage difference VD2.Clause 9: The method of clause 8, wherein the first, positive voltage difference VD1 and the second, negative voltage difference VD2 are selected according to a material composition present at the surface (25) of a sample (7). Clause 10: The method of any of the clauses 1 to 9, further comprising an adjustment step M, for confining a setting for a second scanning operation B for charge compensation. Clause 11: The method of any of the clauses 1 to 10, further comprising setting the first voltage difference VD1=VS1−VK1 between a first sample voltage VS1 applied to the sample (7) and a voltage VK1 of an emitter (301) of primary charged particles within a voltage range about 1 kV. Clause 12: The method of any of the clauses 1 to 11, further comprising setting or confining the second voltage difference VD2 by setting or confining at least one of a sample voltage VS, a voltage VK of an emitter (301) of primary charged particles, and a voltage VE provided to an electrode (133). Clause 13: The method of any of the clauses 1 to 12, further comprising an image acquisition step I for receiving and storing image data acquired during a first image scanning operation step A. Clause 14: The method of any of the clauses 1 to 13, further comprising a collection step C for receiving, analyzing and storing information acquired during a second scanning operation step B for charge compensation. Clause 15: A multi-beam charged particle beam system (1), comprising—an emitter (301) of primary charged particles, connected to an emitter voltage supply for providing an emitter voltage VK to the emitter (301),—a sample voltage supply (503) for providing during use a sample voltage VS to a sample (7) mounted on a sample stage (500) of the multi-beam charged particle beam system (1),—a control unit (800) configured for adjusting at least one of the emitter voltage VK or the sample voltage VS, the control unit (800) further comprising a memory (890) storing software instructions and an operation processor (880) for executing the software instructions, when executed causing the multi-beam charged particle beam system (1) to perform any of the method steps according to clauses 1 to 14.Clause 16: A method of inspection of a FinFET (701) with a multi-beam charged particle imaging system (1), comprising—a first or image scanning operation step A comprising setting a first, positive voltage difference VD1 such that primary charged particle beamlets (3) reach the surface (25.1, 25.2, 25.3) of the FinFET (701) at a landing energy LE within a range of landing energies, where a secondary and backscattered electron yield exceeds an incident beam current of primary charged particles, thereby generating image data and generating positive surface charges at least at regions of the insulator (705) of the FinFET (701),—a second scanning operation step B for charge compensation comprising setting a second, negative voltage difference VD2, such that primary charged particle beamlets (3) are reverted in propagation direction before reaching uncharged regions of the surface (25.1, 25.3) of the FinFET (701), and reach the insulator (705), where the positive surface charges are generated during the first or image scanning operation step A.

Clause 17: The method of clause 16, further comprising iteratively repeating the first or image scanning operation step A and the second scanning operation step B for charge compensation and computing an image of the surface (25.1, 25.2, 25.3) by image processing of a plurality of images generated during iteratively repeating the first or image scanning operation step A.

The disclosure is however not limited to the embodiments or clauses described above, and variations and modifications are possible as well.

### A LIST OF REFERENCE NUMBERS IS PROVIDED

1 multi-beamlet charged particle beam system
3 primary charged particle beamlets, or plurality of primary charged particle beamlets
5 primary charged particle beam spot
7 object
9 secondary electron beamlet or plurality of secondary electron beamlets
11 primary beam path
13 secondary electron beam path
15 secondary charged particle image spot
21 common pupil plane
25 surface of object
61 SE yield curve of first material composition
62 SE yield curve of second material composition
63 low energy transition point
65 high energy transition point
67 first material composition
69 second material composition
71 surface charging
100 object irradiation unit
101 object plane
102 objective lens
103 field lens
108 beam cross over
110 first scanning deflector
112 electrostatic lens
133 electrode
135 first electrical field
137 equipotential lines of extraction field
139 electrical field vector
141 interaction volume
143 scanning direction
149 pre-exposed surface area
151 beam tube segment
153 exit opening of beam tube segment
161 lens coil
163 pole shoe
165 lower pole shoe segment
191 secondary electron trajectory
200 detection unit
205 electron-optical lens
214 aperture filter module
215 movement mechanism
222 second deflector
225 detection or image plane
230 monitoring system
241 scanning line
243 fly-back
245 image patch of single beamlet
251 image of surface segment
284 aperture filter
300 charged-particle multi-beamlet generator
301 emitter of charged particles
303 collimating lenses
304 filter plate
305 multi-aperture arrangement
306 multi-aperture plates
309 primary electron beam
321 intermediate image surface
331 first field lens
333 second field lens
400 beam divider
500 sample stage
503 Sample voltage supply
505 sample platform, such as wafer chuck
600 image sensor or detector
701 FinFET structure
703 silicon wafer
705 silicon dioxide insulator
707 polysilicon gate
709 source
711 drain
713 high-k dielectric
800 control unit
810 imaging control module
820 monitoring control unit
830 primary beam path control module
840 secondary beam path control module
850 stage control module
860 scanning operation control unit
880 Control operation processor
890 memory
2105 optical axis of detection unit

What is claimed is:

1. A method of operating a multi-beam charged particle beam system, the method comprising:
performing a first scanning operation comprising setting a first, positive voltage difference so that primary charged particle beamlets generated by the multi-beam charged particle beam system reach a surface of a sample with a landing energy within a range of landing energies, wherein a secondary and backscattered electron yield due to the primary charged particle beamlets reaching the surface of the sample exceeds an incident beam current of the primary charged particles at the surface of the sample, thereby generating image data and positive surface charges at least at regions of the surface of the sample; and
performing a second scanning operation comprising setting a second, negative voltage difference so that primary charged particle beamlets generated by the multi-beam charged particle beam system: i) are reverted in a propagation direction before reaching uncharged regions of the surface of the sample; and ii) reach the surface of the sample at the regions where the positive surface charges are generated during the first scanning operation.

2. The method of claim 1, wherein an absolute value of the second, negative voltage difference is less than 100V.

3. The method of claim 1, further comprising iteratively repeating the first and second scanning operations.

4. The method of claim 1, wherein each of the first and second scanning operations comprises scanning a plurality of scanning lines, and the method further comprises iteratively repeating the first and second scanning operations for each sequence of scanning lines.

5. The method of claim 3, comprising performing the second scanning operation during a fly-back of each primary charged particle beamlet.

6. The method of claim 1, wherein:
the sample comprises a wafer; and
the method comprises acquiring, during the first scanning operation, an image of a segment of the surface of the wafer, and at least partially compensating a surface charge at the segment of the surface of the wafer during the second scanning operation.

7. The method of claim 6, wherein the second scanning operation is limited to a scanning range at a border or an edge of the segment of the surface of the wafer.

8. The method of claim 1, further comprising:
adjusting an inspection site of the surface of the sample in an object plane of the multi-beam charged particle beam system; and
selecting an image setting comprising selecting the first, positive voltage difference and the second, negative voltage difference,
wherein the sample comprises a wafer.

9. The method of claim 8, comprising selecting the first, positive voltage difference and the second, negative voltage difference based on a material composition present at the surface of the wafer.

10. The method of claim 1, further comprising performing an adjustment to confine a setting for the second scanning operation.

11. The method of claim 1, wherein the first, positive voltage difference is between a voltage applied to the sample and a voltage of an emitter the primary charged particles, and the method comprises setting the first voltage difference to be within a voltage range about 1kV.

12. The method of claim 1, further comprising setting or confining the second voltage difference by setting or confining at least one of a sample voltage, a voltage of an emitter of the primary charged particles, and a voltage provided to an electrode of the multi-beam charged particle beam system.

13. The method of claim 1, further comprising receiving and storing the image data acquired during the first image scanning operation.

14. The method of claim 1, further comprising receiving, analyzing and storing information acquired during the second scanning operation.

15. The method of claim 1, wherein the sample comprises a wafer.

16. A multi-beam charged particle beam system, comprising:
an emitter configured to generate primary charged particles;
an emitter voltage supply connected to the emitter to provide a voltage to the emitter;
a sample voltage supply configured to provide a sample voltage a sample in the multi-beam charged particle beam system; and
a control unit configured to adjust the emitter voltage and/or the sample voltage,
wherein the control unit comprises a memory configured to store software instructions and an operation processor configured to execute the software instructions so that, when the software instructions are executed, the multi-beam charged particle beam system performs:
a first scanning operation comprising setting a first, positive voltage difference so that primary charged particle beamlets generated by the multi-beam charged particle beam system reach a surface of a sample with a landing energy within a range of landing energies, wherein a secondary and backscattered electron yield due to the primary charged particle beamlets reaching the surface of the sample exceeds an incident beam current of the primary charged particles at the surface of the sample, thereby generating image data and positive surface charges at least at regions of the surface of the sample; and
a second scanning operation comprising setting a second, negative voltage difference so that primary charged particle beamlets generated by the multi-beam charged particle beam system: i) are reverted in a propagation direction before reaching uncharged regions of the surface of the sample; and ii) reach the surface of the sample at the regions where the positive surface charges are generated during the first scanning operation.

17. A method of inspecting a FinFET using a multi-beam charged particle beam system, the method comprising:
performing a first scanning operation step comprising setting a first, positive voltage difference so that primary charged particle beamlets generated by the multi-beam charged particle system reach a surface of the FinFET with a landing energy within a range of landing energies, wherein a secondary and backscattered electron yield due to the primary charged particle beamlets reaching the surface of the sample exceeds an incident beam current of the primary charged particles at the surface of the sample, thereby generating image data and generating positive surface charges at least at regions of an insulator of the FinFET; and
performing a second scanning operation comprising setting a second, negative voltage difference so that primary charged particle beamlets generated by the multi-beam charged particle system: i) are reverted in a propagation direction before reaching uncharged regions of the surface of the FinFET; and ii) reach the insulator where the positive surface charges are generated during the first scanning operation.

18. The method of claim 17, further comprising iteratively repeating the first and second scanning operations; and computing an image of the surface by image processing a plurality of images generated during iteratively repeating the first scanning operation.

19. The method of claim 18, comprising performing the second scanning operation during a fly-back of each primary charged particle beamlet.

20. The method of claim 17, further comprising receiving and storing the image data acquired during the first image scanning operation.
